(19) United States
(12) Patent Application Publication
(10) Pub. No.: US 2010/0225330 A1
(43) Pub. Date: Sep. 9, 2010

(54) Method of testing electric fuse, and electric fuse circuit

(75) Inventor: Naotake Watanabe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/659,271

(22) Filed: Mar. 2, 2010

(30) Foreign Application Priority Data
Mar. 5, 2009 (JP) 2009-052690

(51) Int. Cl. G01R 31/02

(52) U.S. Cl. 324/550

(57) ABSTRACT

An object of the present invention is to provide a method of testing an electric fuse which enables to reduce a time for testing. The method of testing an electric fuse according to the present invention comprises: selecting a plurality of disconnection-targeted fuses among a plurality of electric fuses; disconnecting a plurality of disconnection-targeted fuse blocks in tern, each of which includes at least one disconnection-targeted fuse; electrically connecting one terminal of each of the plurality of disconnection-targeted fuses to a first node and connecting another terminal of the each disconnection-targeted fuse to a second node, after disconnecting; and judging whether or not all of said plurality of disconnection-targeted fuses are disconnected after electrically connecting, by applying a voltage to the first node to judge whether or not a current flows between the first node and the second node.

### INCORPORATION BY REFERENCE

This patent application claims a priority on convention based on Japanese Patent Application No. 2009-052690. The disclosure thereof is incorporated herein by reference.

### BACKGROUND OF THE INVENTION

1. Field of the Invention

The present invention relates to a method of testing an electric fuse and to an electric fuse circuit.

2. Description of Related Art

Electric fuses are widely used as non-volatile memory elements for RAM redundancy relief (redundancy circuit) or CHIP information storage (IDFUSE). Electric fuses are disconnected, if necessary. In recent years, the number of electric fuses provided in one device is in a tendency of increasing. As the number of electric fuses increases, it becomes more difficult to select only a desired electric fuse to be disconnected among a large number of electric fuses.

A related art is described in document 1 (Japanese patent publication JP2006-197272A). FIG. 1 is a circuit diagram showing a semiconductor device described in document 1. This semiconductor device includes electric fuses (102a, 102b) provided in correspondence with redundant memory cells, a selector 103 for selecting the electric fuses (102a, 102b) based on a data signal indicating a defective memory cell, a disconnecting circuit 105 for disconnecting the selected electric fuses (102a, 102b) by applying a current to flow therein, a switching signal generation circuit 104 for generating a switching signal based on disconnection states of the electric fuses (102a, 102b), and a changeover circuit for changeover from the defective memory cell to the redundant memory cell based on the switching signal.

Another related art is described in document 2 (Japanese patent publication JP2007-172720A). FIG. 2 is a circuit diagram showing an electric fuse circuit described in document 2. This electric fuse circuit includes a plurality of electric fuse cores 111 each having an electric fuse element 112 and a switching transistor 113 connected in series, and shift registers 114 which are connected to the plurality of electric fuse cores 111 for programming the electric fuse elements 112. The shift registers 114 sequentially generate program enable signals to be transferred to the electric fuse cores 111 so that the switching transistors 113 are electrically conducted in sequence according to information of the program enable signals and program data. Thus, the electric fuse elements 113 are blown out one by one.

### SUMMARY OF THE INVENTION

The electric fuses are disconnected by applying an overcurrent to flow therein. At this time, a large current is required in order to disconnect all of the large number of electric fuses at the same time. In order to disconnect each electric fuse without fail, the electric fuse circuit described in document 2 is configured so that the switching transistors connected to the plurality of electric fuses are electrically conducted one by one.

By the way, for a device having a large number of electric fuses, it is desirable to execute a test whether or not the disconnection-targeted electric fuses are surely disconnected after the disconnection-targeted fuses are disconnected. However, in document 1 and 2, there is no description about testing whether or not the disconnection-targeted fuses are surely disconnected.

In an electric fuse circuit configured to electrically conduct the switches one by one which are connected to a group of disconnection-targeted electric fuses, it is considered that the switches are also electrically conducted one by one at the time of testing. Thus, it can be individually judged whether or not each of the disconnection-targeted electric fuses is electrically conducting. However, in this method, there is a problem that a time for testing is increased as the number of the disconnection-targeted electric fuses is increased.

A method of testing an electric fuse according to the present invention includes: selecting a plurality of disconnection-targeted fuses among a plurality of electric fuses; a plurality of disconnection-targeted fuse blocks in tern, each of which includes at least one disconnection-targeted fuse; electrically connecting one terminal of each of the plurality of disconnection-targeted fuses to a first node and connecting another terminal of the each disconnection-targeted fuse to a second node, after the disconnecting; and judging whether or not all of the plurality of disconnection-targeted fuses are disconnected after the electrically connecting, by applying a voltage to said first node to judge whether or not a current flows between the first node and the second node.

According to the present invention, after the each of the disconnection-targeted fuses is disconnected, only the plurality of disconnection-targeted fuses are connected to the second node at the other terminal. Accordingly, only the plurality of disconnection-targeted fuses are connected in parallel between the first node and the second node. Under this condition, if all of the plurality of disconnection-targeted fuses are correctly disconnected, a current does not flow when a voltage is applied to the first node. On the other hand, if there is a disconnection-defective fuse in the plurality of disconnection-targeted fuses, a current flows. Accordingly, it can be possible to judge whether or not the plurality of disconnection-targeted fuses are disconnected by one time, and a time for testing can be reduced.

An electric fuse circuit according to the present invention includes: a plurality of electric fuses, each of which is connected to a first node at one terminal and is connected to a second node at another terminal; a switch circuit provided between each of the plurality of electric fuses and the second node; a selector circuit configured to control the switch circuit so that the plurality of disconnection-targeted fuses selected from the plurality of electric fuses are disconnected by currents flowing between the first node and the second node; and a test circuit configured to control the switch circuit at a time of testing. The selector circuit controls the switch circuit so that the plurality of disconnection-targeted fuses are disconnected in turn. The test circuit controls the switch circuit so that only the plurality of disconnection-targeted fuses are connected to the second node at the other terminal.

According to the present invention, a method of testing an electric fuse and an electric fuse circuit, which can reduce a time for testing.

### BRIEF DESCRIPTION OF DRAWINGS

FIG. 1 is a circuit diagram showing a semiconductor device described in document 1;

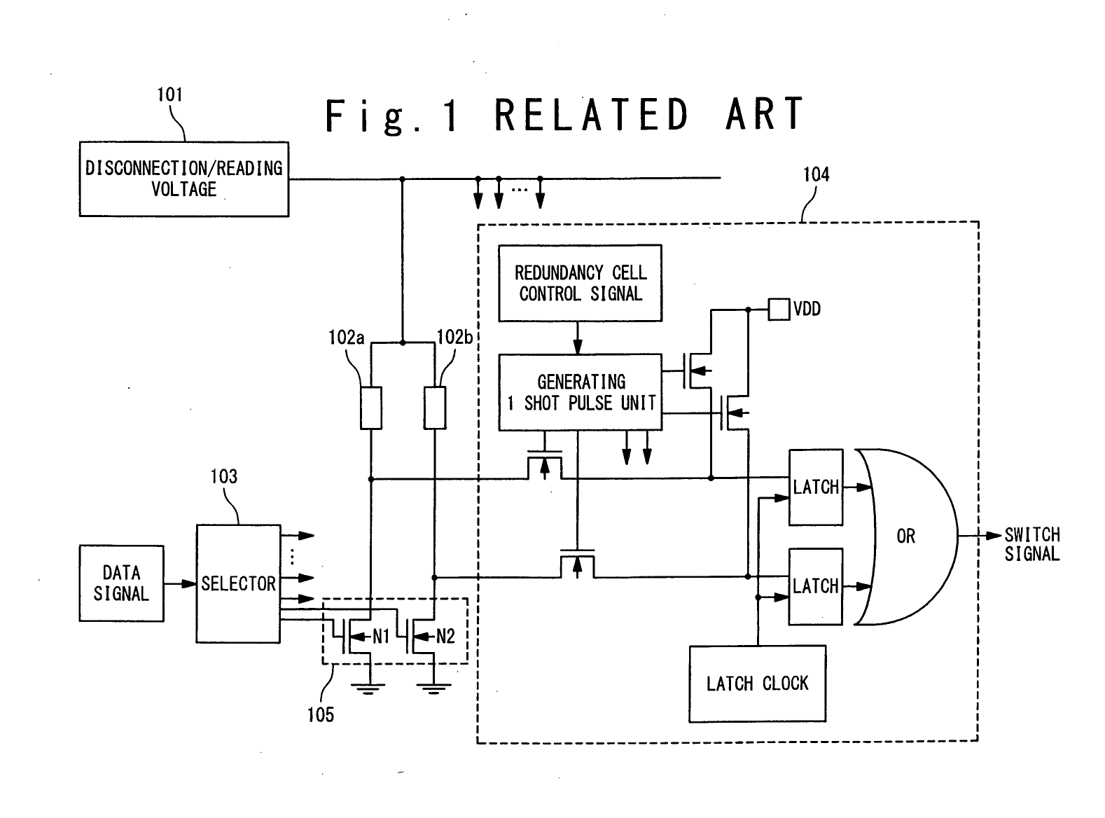

FIG. 2 is a circuit diagram showing an electric fuse circuit described in document 2;

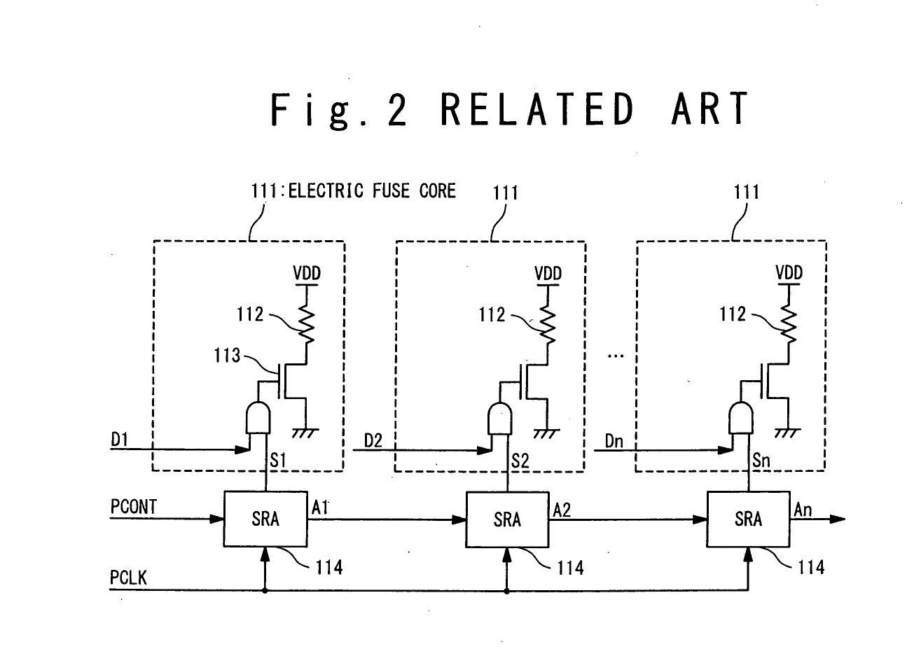

FIG. 3 is a circuit diagram showing an electric fuse circuit; and

FIG. 4 is a flow chart showing an operating method of the electric fuse circuit.

### DESCRIPTION OF THE PREFERRED EMBODIMENTS

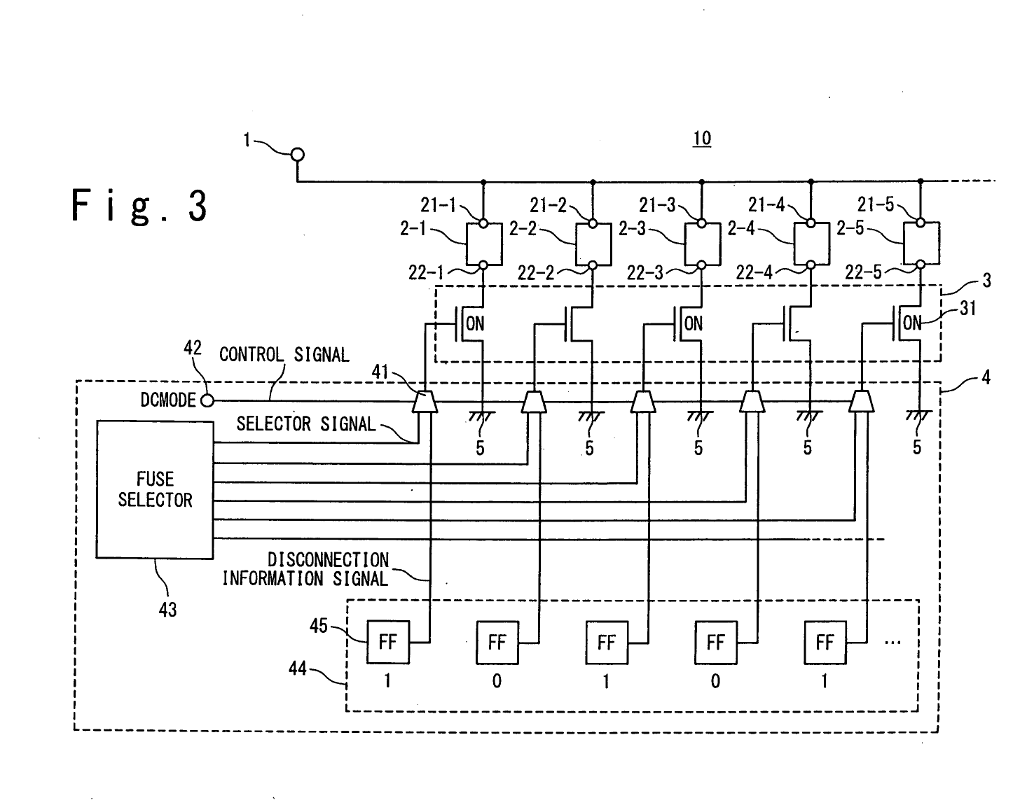

Referring to the attached drawings, an embodiment of the present invention will be described below. FIG. 3 is a circuit diagram showing an electric fuse circuit 10 according to the present embodiment.

As shown in FIG. 3, the electric fuse circuit 10 includes a plurality of electric fuses 2 (2-1 to 2-5), a switch circuit 3, and a changeover control circuit 4.

The plurality of electric fuses 2 are connected in parallel between a first node 1 and a ground 5 (i.e., second node). Each of the plurality of electric fuses 2 has one terminal 21 (21-1 to 21-5) and another terminal 22(22-1 to 22-5). The each electric fuse 2 is electrically connected to the first node 1 through the one terminal 21 and is connected to the ground 5 through the other terminal 22.

The switch circuit 3 is provided for switching whether or not electrically connecting the other terminal 22 of the each electric fuse 2 to the ground 5. The switch circuit 3 includes a plurality of NMOS transistors 31 corresponding to the plurality of electric fuses 2. Each of the plurality of NMOS transistors 31 is provided between the other terminal 22 of the each electric fuse 2 and the ground 5.

The changeover control circuit 4 is a circuit for controlling the switch circuit 3. The changeover control circuit 4 includes a plurality of multiplexer circuits 41, a DCMODE terminal 42 (combined resistance measurement mode terminal), a fuse selector circuit 43, and an electric fuse disconnection information register circuit 44 (test circuit).

The plurality of multiplexer circuits 41 are provided in correspondence with the plurality of NMOS transistors 31. Each of the plurality of multiplexer circuits 41 has an output terminal, two input terminals and a control terminal. The output terminal thereof is connected to a gate terminal of the each NMOS transistor 31. One of the two input terminals is connected to the fuse selector circuit 43, and the other thereof is connected to the electric fuse disconnection information register circuit 44. The control terminal thereof is connected to the DCMODE terminal 42. In the each multiplexer circuit 41, one of the two input signals inputted through the two input terminals is outputted through the output terminal, according to a logic level of a control signal supplied from the DCMODE terminal 42.

The DCMODE terminal 42 is provided for changeover between a test mode and a disconnection mode. The DCMODE terminal 42 supplies the control signal to the each multiplexer circuits 41 such that a signal supplied from the fuse selector circuit 43 is outputted in the disconnection mode and that a signal supplied from the electric fuse disconnection information register circuit 44 is outputted in the test mode.

The fuse selector circuit 43 is provided for selecting a plurality of disconnection-targeted fuses (a group of fuses to be disconnected) among the plurality of electric fuses 2 when disconnecting. The fuse selector circuit 43 supplies the selector signal to the each multiplexer circuits 41 such that the NMOS transistors 31 connected to the plurality of disconnection-targeted fuses 2 are electrically conducting in sequence in the disconnection mode.

The electric fuse disconnection information register circuit 44 is provided for selecting only the group of the disconnection-targeted fuses when testing. The electric fuse disconnection information register circuit 44 includes a plurality of registers 45 corresponding to the plurality of electric fuses 2. Each of the plurality of registers 45 stores information (fuse disconnection information) indicating whether or not the corresponding electric fuse 2 is the disconnection-targeted fuse. Each of the registers 45 supplies a signal corresponding to the fuse disconnection information as the disconnection information signal, to the each multiplexer circuit 41. The fuse disconnection information is obtained from, for example, fail information stored in memory BIST (Built-In Self Test) or a tester for testing the electric fuses, and is stored in the electric fuse disconnection information register circuit 44.

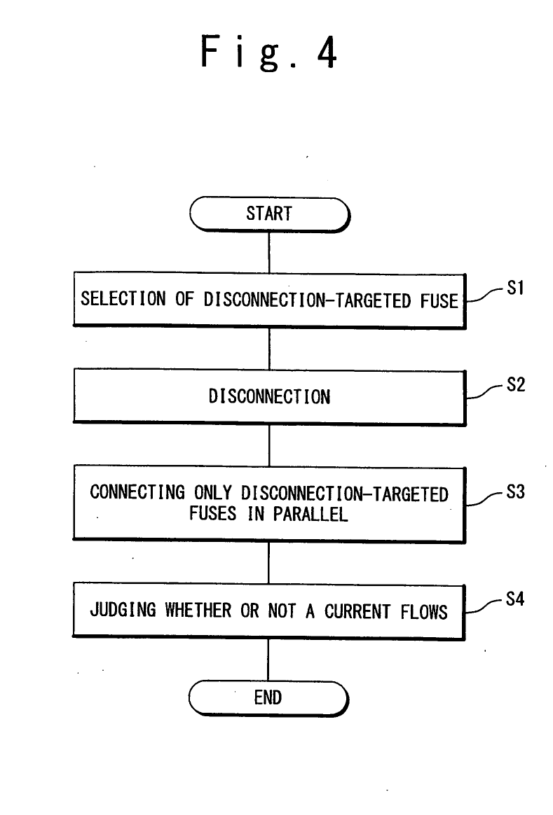

Subsequently, a method of operating the electric fuse circuit according to the present embodiment will be described below. FIG. 4 is a flow chart showing a method of operating the electric fuse circuit.

Step S1: Selection of Disconnection-targeted Fuse

Firstly, prior to disconnecting the disconnection-targeted fuse group, the control signal corresponding to the disconnection mode is supplied from the DCMODE terminal 42 to the each multiplexer circuit 41. Upon receipt of the control signal, the each multiplexer circuit 41 is set so as to output the selector signal supplied from the fuse selector circuit 43. Meanwhile, a voltage for disconnecting the disconnection-targeted fuses is applied to the first node 1 by a tester (not shown). Under this condition, the fuse selector circuit 43 selects the disconnection-targeted fuse group among the plurality of electric fuses 2. In the present embodiment, it is presumed that the electric fuses 2-1, 2-3 and 2-5 are selected as the disconnection-targeted fuse group.

Step S2: Disconnection

Then, the fuse selector circuit 43 sequentially supplies the selector signal to the each multiplexer circuits 41 corresponding to the each disconnection-targeted fuse (2-1, 2-3, 2-5). The selector signal is supplied to the each NMOS transistor 31 through the each multiplexer circuit 41. The each NMOS transistor 31 supplied with the selector signal becomes an electrically conducting state. Thus, there flows a current from the first node 1 to the ground 5 through the each disconnection-targeted fuse (2-1, 2-3, 2-5) so that the each disconnection-targeted fuse (2-1, 2-3, 2-5) is disconnected. At this time, since the selector signals are sequentially supplied, the disconnection-targeted fuses (2-1, 2-3, 2-5) group is disconnected one by one in turn. Since the current flows through the targeted fuses one by one in turn, an adequate amount of current can flow through the each disconnection-targeted fuses (2-1, 2-3, 2-5). Accordingly, the each disconnection-targeted fuse can be surely disconnected.

Step S3: Connecting Only Disconnection-targeted Fuses in Parallel

Subsequently, a test is executed to judge whether or not the disconnection-targeted fuses (2-1, 2-3, 2-5) are correctly disconnected. Prior to executing a test, the control signal indicating the test mode is firstly supplied from the DCMODE terminal 42 to the each multiplexer circuit 41. Thus, the each multiplexer circuits 41 is set so as to output the disconnection information signal supplied from the electric fuse disconnection information register circuits 44. In this step, the electric fuse disconnection information register circuits 44 supplies a signal for electrically conducting the NMOS transistors 31 as the disconnection information signal, to the each multiplexer circuit 41 corresponding to the each disconnection-targeted fuses (2-1, 2-3, 2-5). Meanwhile, a signal for electrically switching off the NMOS transistors 31 is supplied as the disconnection information signal, to the each multiplexer circuit 41 corresponding to the non-disconnection fuses (2-2, 2-4) other than the disconnection-targeted fuses (2-1, 2-3, 2-5) among the plurality of electric fuses 2.

By this process as described above, the terminals 21 of the disconnection-targeted fuses (2-1, 2-3, 2-5) are connected to the first node 1 and the other terminals 22 thereof are connected to the ground 5 through the NMOS transistors 31. Meanwhile, the other terminals 22 of the non-disconnection fuses (2-2, 2-4) are electrically interrupted from the ground 5. That is, only the disconnection-targeted fuses (2-1, 2-3, 2-5) are connected in parallel between the first node 1 and the ground 5.

Step S4: Judging Whether or Not a Current Flows

Subsequently, a voltage is applied to the first node 1 by the tester. At this time, if all of the disconnection-targeted fuses (2-1, 2-3, 2-5) are disconnected, no current flows even though the voltage is applied. Whereas, if a disconnection-defective fuse is included in the disconnection-targeted fuses (2-1, 2-3, 2-5), there flows a current. Accordingly, it is possible to judge whether or not a disconnection-defective fuse exists by judging whether or not a current flows, using the tester. At this time, since a judgment can be executed only by once applying the voltage to the first node 1, the time for testing can be reduced.

In the present embodiment, the each disconnection-targeted fuse (2-1, 2-3, 2-5) is disconnected one by one in turn when disconnecting. However, in the case where currents required for disconnection can be applied to flow to the plurality of disconnection-targeted fuses (2-1, 2-3, 2-5) at the same time, there is no need to disconnect the fuses one by one. That is, the entire disconnection-targeted fuses (2-1, 2-3, 2-5) group is divided into a plurality of blocks (disconnection-targeted fuse blocks) each including a plurality of disconnection-targeted fuses. Then, the disconnection-targeted fuse blocks are disconnected one by one block in turn. At this time, the plurality of disconnection-targeted fuses included in the each disconnection-targeted block are disconnected at the same time. Such a disconnecting method can be realized by, for example, devising a pathway between the fuse selector circuit 43 and the multiplexer circuits 41. When such a disconnecting method is employed, an effect similar to that described in the present embodiment can be obtained.

What is claimed is:

1. A method of testing an electric fuse comprising:
selecting a plurality of disconnection-targeted fuses among a plurality of electric fuses;
disconnecting a plurality of disconnection-targeted fuse blocks in tern, each of which includes at least one said disconnection-targeted fuse;
electrically connecting one terminal of each of said plurality of disconnection-targeted fuses to a first node and connecting another terminal of said each disconnection-targeted fuse to a second node, after said disconnecting; and
judging whether or not all of said plurality of disconnection-targeted fuses are disconnected after said electrically connecting, by applying a voltage to said first node to judge whether or not a current flows between said first node and said second node.

2. The method of testing an electric fuse according to the claim 1, wherein said disconnecting includes disconnecting said each disconnection-targeted fuse by a current.

3. The method of testing an electric fuse according to the claim 1, wherein said second node is grounded.

4. An electric fuse circuit comprising:
a plurality of electric fuses, each of which is connected to a first node at one terminal and is connected to a second node at another terminal;
a switch circuit provided between each of said plurality of electric fuses and said second node;
a selector circuit configured to control said switch circuit so that a plurality of disconnection-targeted fuse blocks, each of which includes at least one said disconnection-targeted fuse, are disconnected in turn, by currents flowing between said first node and said second node; and
a test circuit configured to control said switch circuit at a. time of testing;
wherein said selector circuit controls said switch circuit so that said plurality of disconnection-targeted fuses are disconnected in turn, and
said test circuit controls said switch circuit so that only said plurality of disconnection-targeted fuses are connected to said second node at said other terminal.
